(19) United States
(12) Patent Application Publication
(10) Pub. No.: US 2023/0062355 A1
(43) Pub. Date: Mar. 2, 2023

(54) TOOL-FREE PCIE FIXING APPARATUS

(71) Applicant: DONGGUAN RAMAXEL MEMORY TECHNOLOGY LIMITED, Dongguan City (CN)

(72) Inventors: Guangyi ZHANG, Dongguan City (CN); Dingguo HUANG, Dongguan City (CN)

(21) Appl. No.: 17/867,524

(22) Filed: Jul. 18, 2022

(30) Foreign Application Priority Data
Sep. 1, 2021 (CN) 202111020002.3

(51) Int. Cl. H05K 7/14; G06F 1/18

(52) U.S. Cl. CPC H05K 7/1487; G06F 1/185; H05K 7/1417

(57) ABSTRACT

The present application provides a tool-free PCIE fixing apparatus, including: a Riser module bracket; a plurality of PCIE card connectors, each configured to fix a PCIE card; a die casting, in an upright state and fixed at one side of the Riser module bracket along a width direction thereof; and a pressing fixation plate, being in an upright state and pivoted at one side of the Riser module bracket along the width direction thereof Δn inner side of the pressing fixation plate is provided with locking pieces. The die casting defines therein locking holes configured to form elastic snap-fitting connection with the locking pieces, respectively. Each of the plurality of PCIE card connectors defines therein a locking slot configured to allow one of the locking pieces to pass through.

### CROSS-REFERENCE TO RELATED APPLICATIONS

Pursuant to 35 U.S.C. § 119 and the Paris Convention, this application claims the benefit of Chinese Patent Application No. 202111020002.3 filed Sep. 1, 2021. The contents of all of the aforementioned applications, including any intervening amendments thereto, are incorporated herein by reference.

### TECHNICAL FIELD

The present application relates to the technical field of peripheral component interconnect express (PCIE) fixation, and more particularly to a tool-free PCIE fixing apparatus.

### BACKGROUND

PCIE cards are generally fixed in the server via screws, that is, the PCIE cards are directly inserted into the PCIE interfaces, and then blanks of the PCIE cards are installed in a chassis by the screws. Since the existing server generally has at least two, three, ore more PCIE cards included in each Riser module, and generally has at least three Riser modules, thus, no matter the installation or disassembly, additional tools are required to operate the screws, which results in much inconvenience for the users and the maintenance personnel, and a waste of time.

Moreover, the server has a limited width, while in the existing technology, the Riser module adopts a plastic fixation interface to fix the PCIE cards. However, the plastic fixation interface is generally thick. In case that a plurality of the Riser modules are arranged side by side in the width direction of the server, the plastic fixation interfaces of the plurality of the Riser modules occupy a certain space in the width direction of the server, which may result in insufficient space in the width direction of the server.

### SUMMARY

In order to tackle the deficiencies of above-described problems, it is an object of the present application to provide a tool-free PCIE fixing apparatus.

To achieve the above object, the present application adopts the following technical solutions:

A tool-free PCIE fixing apparatus, comprises: a Riser module bracket, a plurality of PCIE card connectors, a die casting, and a pressing fixation plate.

Each of the plurality of PCIE card connectors is configured to fix a PCIE card.

The die casting is in an upright state and fixed at one side of the Riser module bracket along a width direction of the Riser module bracket.

The pressing fixation plate is in an upright state and pivoted at one side of the Riser module bracket along the width direction of the Riser module bracket.

An inner side of the pressing fixation plate is provided with locking pieces. The die casting defines therein locking holes configured to form elastic snap-fitting connection with the locking pieces, respectively. Each of the plurality of PCIE card connectors defines therein a locking slot configured to allow one of the locking pieces to pass through.

The pressing fixation plate is configured to: be rotated inward to enable free ends of the locking pieces to pass through the locking slots and be locked into the corresponding locking holes, whereby achieving position limitation and fixation of a plurality of the PCIE cards; and be rotated outward to enable locking pieces to be released from the corresponding locking holes, whereby releasing the position limitation and fixation of the plurality of the PCIE cards.

In a further embodiment of the present application, the die casting defines therein torsion spring mounting slots. Torsion springs are installed within the torsion spring mounting slots, respectively. In a state that the torsion springs are installed within the torsion spring mounting slots, two torsion arms of each of the torsion springs are kept in parallel, and a width of an interval between the two torsion arms is smaller than a width of a corresponding locking hole.

In a further embodiment of the present application, each of the locking pieces comprises a rod portion and an end portion. An inner end of the rod portion is in vertically fixed connection with the pressing fixation plate, and an outer end of the rod portion is in fixed connection with the end portion. A diameter of the end portion is greater than the width of the interval between the two torsion arms of each of the torsion springs.

In a further embodiment of the present application, the end portion is in a spherical or circular shape.

In a further embodiment of the present application, the Riser module bracket comprises a fixation panel. The pressing fixation plate is pivoted at the fixation panel. The die casting is fixed at an inner side of the fixation panel. The fixation panel defines therein through holes at positions corresponding to the locking holes.

In a further embodiment of the present application, the Riser module bracket comprises a first connecting panel and a second connection panel. In a state where the PCIE cards are installed within the Riser module bracket, a length direction of the first connection panel corresponds to a length direction of each of the PCIE cards, and a length direction of the second connection panel corresponds to a width direction of each of PCIE cards. An end surface of one end of the second connection panel away from the first connection panel is served as the fixation panel.

In a further embodiment of the present application, an edge of a side surface of the fixation panel is provided with a first rolling edge. An edge of a side surface of the pressing fixation plate is provided with a second rolling edge matching with the first rolling edge. The first rolling edge and the second rolling edge are connected via a pin.

In a further embodiment of the present application, each of the plurality of PCIE card connectors comprises a connection portion and a matching portion. The connection portion is fixed at a side surface in a width direction of each of the PCIE cards. The matching portion is connected with the connection portion in a manner perpendicular to each other. The matching portion is arranged at an outer side of the fixation panel and in parallel with the fixation panel. The matching portion defines therein a locking slot.

In a further embodiment of the present application, an opening of the locking slot faces upwards.

In a further embodiment of the present application, positioning bumps are arranged at edges of the through holes, respectively, at an outer side of the fixation panel. An outer curvature of each of the positioning bumps is adapted to an outer curvature of the locking slot, so that the locking slots can be stuck at outer sides of the positioning bumps, respectively.

Advantages of the tool-free PCIE fixing apparatus according to embodiments of the present application are summarized as follows: in the present application, the pressing fixation plate is pivoted at the Riser module bracket, and the pressing fixation plate is arranged in an upright manner and pivoted at the Riser module bracket at one side of the width direction of the Riser module bracket, which occupies little space in the width direction of the Riser module bracket since the pressing fixation plate can be constructed to be very thin. Moreover, the pressing fixation plate cooperates with the die casting in a snap-fitting connection, which can quickly fix the PCIE cards and realize the tool-free installation of the PCIE cards, thus being easy to operate and maintain.

The above description is only an overview of the technical solution of the present application. In order to make those skilled in the art to understand the technical means of the present application more clearly and to implement the technical solutions according to the context of the specification, and in order to make the objects, features, and advantages of the present application more clearly understood, detailed description of embodiments of the present application are provided hereinbelow.

### BRIEF DESCRIPTION OF THE DRAWINGS

In order to more clearly illustrate the technical solutions in the embodiments of the present application, the drawings that need to be used in the description of the embodiments or the existing technology will be briefly described hereinbelow. Obviously, the accompanying drawings in the following description are only some embodiments of the present application. For those skilled in the art, other drawings can be obtained based on these drawings without creative work.

FIG. 1 is a structure schematic diagram of a specific embodiment of a tool-free PCIE fixing apparatus of the present application, in which, the PCIE cards are in a state released from fixation;

FIG. 2 is a structure schematic diagram of a specific embodiment of a tool-free PCIE fixing apparatus of the present application, in which, the PCIE cards are in a fixation state;

FIG. 3 is an exploded view of a specific embodiment of a tool-free PCIE fixing apparatus of the present application;

FIG. 4 is a cross sectional view of a specific embodiment of a tool-free PCIE fixing apparatus of the present application;

FIG. 5 is a structure schematic diagram of a die casting of a specific embodiment of a tool-free PCIE fixing apparatus of the present application;

FIG. 6 is a structure schematic diagram of a pressing fixation plate of a specific embodiment of a tool-free PCIE fixing apparatus of the present application;

FIG. 7 is a structure schematic diagram of a torsion spring of a specific embodiment of a tool-free PCIE fixing apparatus of the present application; and

FIG. 8 is a structure schematic diagram of a PCIE card connector of a specific embodiment of a tool-free PCIE fixing apparatus of the present application.

In the drawings, the following reference numerals are adopted: 1: Riser module bracket; 11: Fixation panel; 12: First rolling edge; 13: Through hole; 14: Positioning bump; 15: First connection panel: 16: Second connection panel; 2: Pressing fixation plate; 21: Locking piece; 211: Rod portion; 212: End portion; 22: Second rolling edge; 3: Die casting; 31: Torsion spring mounting slot; 311: Torsion spring; 32: Locking hole; 4: PCIE card connector; 41: Connection portion; 42: Matching portion; 421: Locking slot; 5: Pin; and 100: PCIE card.

### DETAILED DESCRIPTION OF EMBODIMENTS

The technical solutions of the present application will be clearly and completely described below with reference to the specific embodiments of the present application. Obviously, the described embodiments are part of, rather than all, the embodiments of the present application. Based on the embodiments of the present application, all other embodiments obtained by those of ordinary skill in the art without creative efforts shall fall within the protection scope of the present application.

It is to be understood that when used in this specification and claims, the terms “comprising” and “containing” indicate the presence of the described features, integers, steps, operations, elements and/or components, but do not exclude the presence or addition of one or more other features, integers, steps, operations, elements and/or components.

It is also to be understood that the terminology used in this specification of the present application is for the purpose of describing particular embodiments only, but is not intended to limit the present application. As used in this specification and the appended claims, the singular forms “a,” “an,” and “the” are intended to include the plural unless otherwise clearly indicated in the context.

It should also be further understood that, as used in this specification and the appended claims, the term “and/or” refers to and including any and all possible combinations of one or more of the associated listed items.

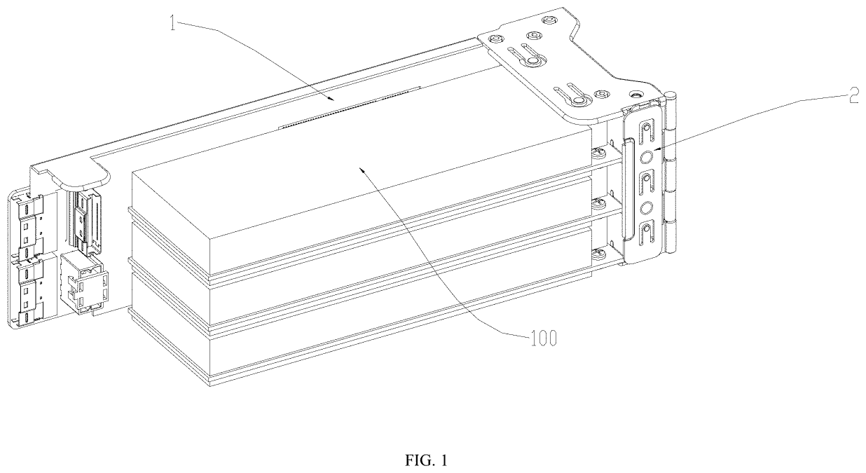

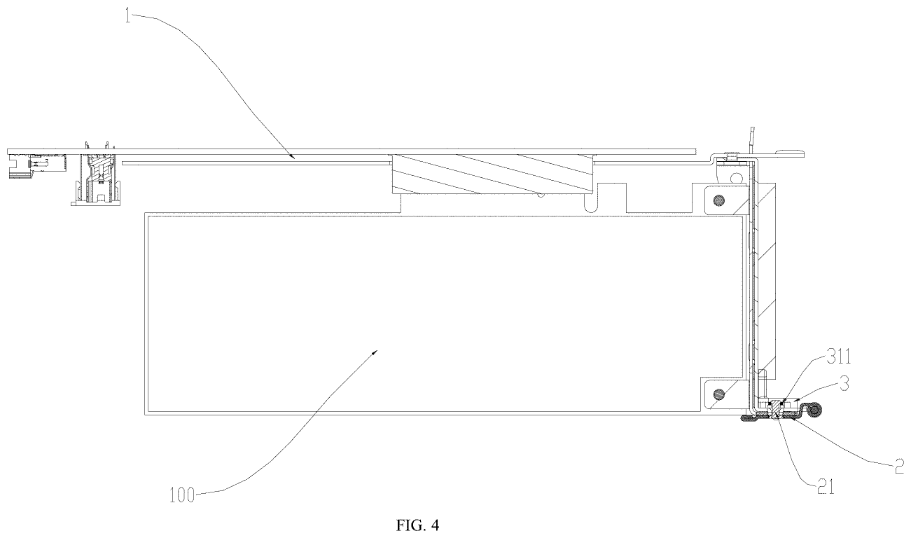

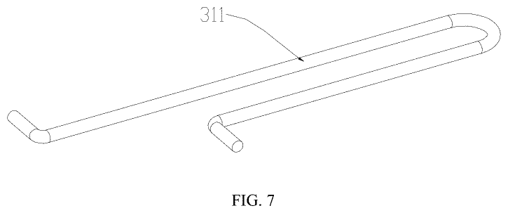

The present application discloses a tool-free PCIE fixing apparatus, as shown in FIGS. 1-8, the tool-free PCIE fixing apparatus comprises: a Riser module bracket 1, a plurality of PCIE card connectors 4, and a pressing fixation plate 2.

Each of the plurality of PCIE card connector 4 is configured to fix a PCIE card. The die casting 3 is in an upright state and fixed at one side of the Riser module bracket 1 along a width direction thereof. The pressing fixation plate 2 is in an upright state and pivoted at one side of the Riser module bracket 1 along the width direction thereof. An inner side of the pressing fixation plate 2 is provided with locking pieces 21, the die casting 3 defines therein locking holes 32 configured to form elastic snap-fitting connection with the locking pieces 21. Each of the plurality of PCIE card connectors 4 defines therein a locking slot 421 configured to allow one of the locking pieces 21 to pass through. The pressing fixation plate 2 is configured to: be rotated inward to enable free ends of the locking pieces 21 to pass through the locking slots 421 and be locked into the corresponding locking holes 32, whereby achieving the position limitation and fixation of the PCIE cards. The pressing fixation plate 2 is also configured to be rotated outward to enable locking pieces 21 to be released from the corresponding locking holes 32, whereby releasing the position limitation and fixation of the PCIE cards.

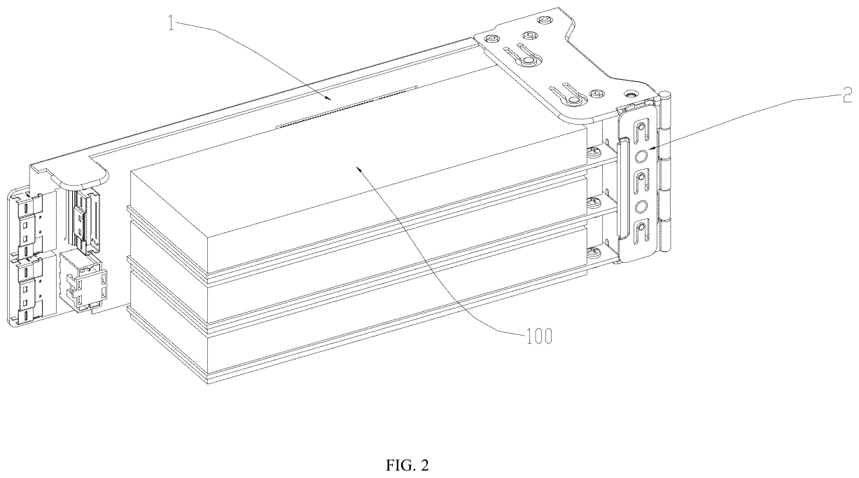

FIG. 1 is a state released from position limitation and fixation of the PCIE cards. FIG. 2 is a state of the position limitation and fixation of the PCIE cards. As shown in FIGS. 1-2, whatever the PCIE cards are switched from the released state to the fixation stated or switched from the fixation state to the released state, it is no need to use tools such as screws or screwdrivers, thus being convenient. In addition, both the pressing fixation plate 2 and the die casting 3 are arranged in an upright manner along the Riser module bracket 1, and can be constructed to be very thin, thus only occupy very little space along the width direction of the Riser module bracket 1. Moreover, the pressing fixation plate 2 cooperates with the die casting 3 in a snap-fitting connection, which can quickly fix the PCIE cards and realize the tool-free installation of the PCIE cards, thus being easy to operate and maintain.

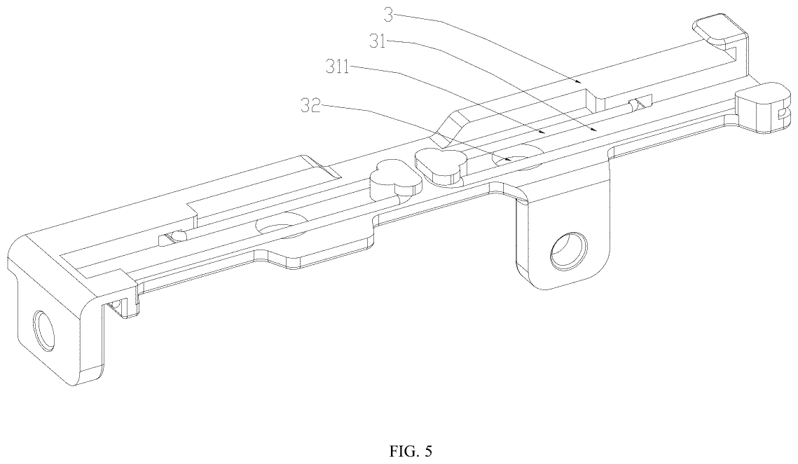

Furthermore, as shown in FIG. 5, the die casting 3 defines therein torsion spring mounting slots 31. Torsion springs 311 are installed within the torsion spring mounting slots 31, respectively. After the torsion springs 311 are installed within the torsion spring mounting slots 31, two torsion arms of each of the torsion springs 311 are kept in parallel, and a width of an interval between the two torsion arms is smaller than a width of a corresponding locking hole 32. The purpose of this configuration is to achieve elastic snap-fitting connection, that is, when the PCIE cards need to be fixed, the outer ends of the locking pieces will cause temporary elastic deformation and in turn opening of the two torsion arms of each torsion spring 311 during the snap-fitting process. After being clamped, since the width of the interval between the two torsion arms is smaller than the width of the corresponding locking hole 32 in the absence of an external force, the locking piece 21 can be clamped by the corresponding torsion spring 311. When the PCIE cards need to be released, the two torsion arms of each of the torsion springs 311 are elastically deformed and opened again, and the locking piece 21 will be released from the corresponding torsion spring 311. The torsion spring 311 is used to fix the locking piece 21, which is not only convenient to use, but also will not be damaged even after a long term usage. Compared with the long term usage of fixation by screws that would cause damage the connection vacancy and result in weak connection, the use of torsion spring 311 for fixation in the present application is able to avoid such negative effects.

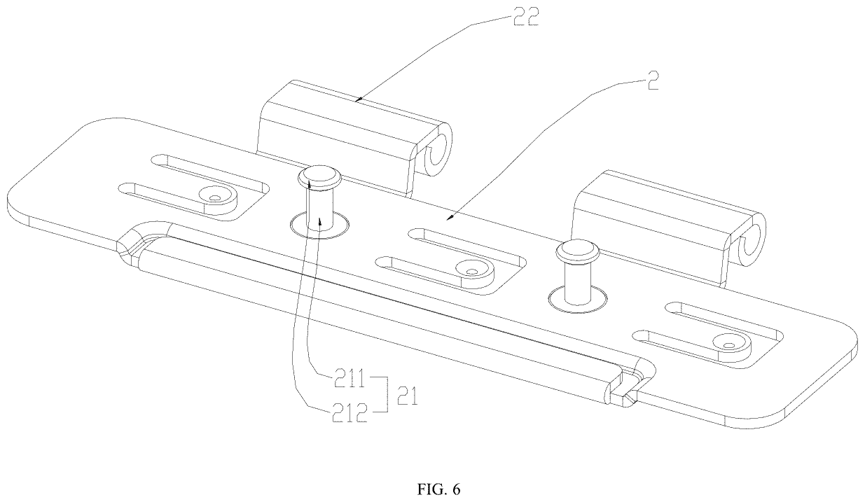

In some embodiments, as shown in FIG. 6, each of the locking pieces 21 comprises a rod portion 211 and an end portion 212. An inner end of the rod portion 211 is in vertically fixed connection with the pressing fixation plate 2, and an outer end of the rod portion 211 is in fixed connection with the end portion 212. A diameter of the end portion 212 is greater than a diameter of the rod portion 211, and the diameter of the end portion 212 is greater than the width of the interval between the two torsion arms of each of the torsion springs. Preferably, the end portion 212 is in a spherical or circular shape.

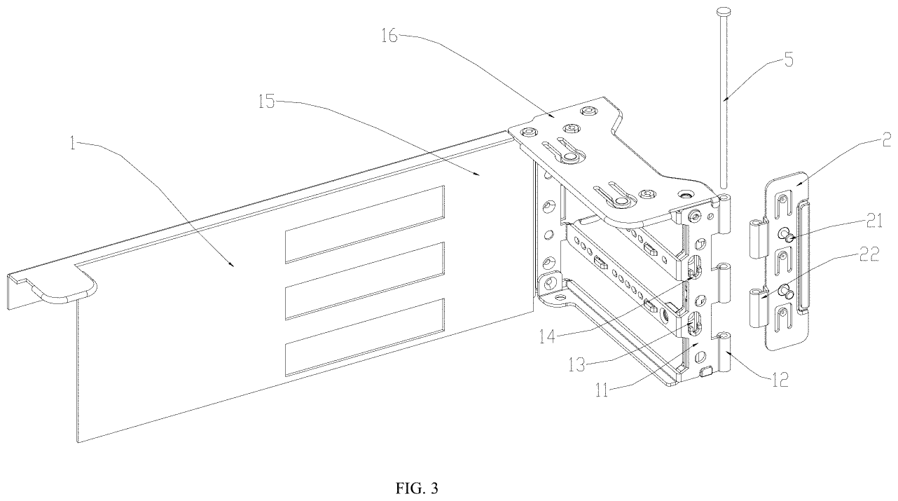

In some embodiments, as shown in FIG. 3, the Riser module bracket 1 comprises a first connecting panel 15 and a second connection panel 16. In a state where the PCIE cards 100 are installed within the Riser module bracket 1, a length direction of the first connection panel 15 corresponds to a length direction of each of the PCIE cards 100, and a length direction of the second connection panel 16 corresponds to a width direction of each of PCIE cards 100. An end surface of one end of the second connection panel 16 away from the first connection panel 15 is served as the fixation panel 11. The pressing fixation plate 2 is pivoted at the fixation panel 11; the die casting 3 is fixed at an inner side of the fixation panel 11, and the fixation panel 11 defines therein through holes 1 at positions corresponding to the locking holes 32. In order to facilitate the locking piece 21 to pass through, preferably, the through holes 13 are configured to be reniform through holes 13.

In the above embodiments, a part of the Riser module bracket 1 is directly used as the fixation panel 11, and thus no additional similar structures is required, the configuration of the present application is thus simple and convenient.

In some embodiment, as shown in FIG. 3, an edge of a side surface of the fixation panel 11 is provided with a first rolling edge 12; an edge of a side surface of the pressing fixation plate 2 is provided with a second rolling edge 22 matching with the first rolling edge 12; and the first rolling edge 12 and the second rolling edge 22 are connected via a pin 5. By adopting rolling edges in fitness with the pin 5, it is not required to occupy the space in the original tight width direction of the Riser module bracket 1.

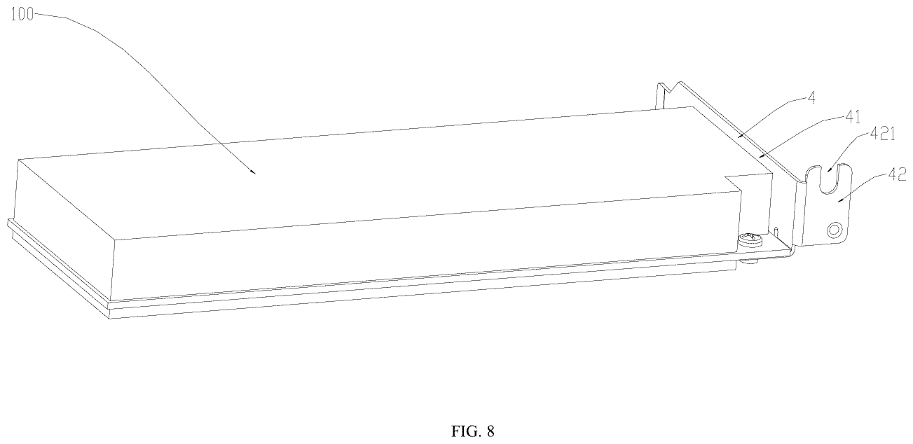

In some embodiments, as shown in FIG. 8, each of the plurality of PCIE card connectors 4 comprises a connection portion 41 and a matching portion 42. The connection portion 41 is fixed at a side surface in a width direction of each of the PCIE cards 100. The matching portion 42 is connected with the connection portion 41 in a manner perpendicular to each other. The matching portion 42 is arranged at an outer side of the fixation panel 11 and in parallel with the fixation panel 11. The matching portion 42 defines therein a locking slot 421. An opening of the locking slot 421 faces upwards. In other embodiments, the locking slot 421 is substituted by holes, but preferably in the form of the locking slots 421. The use of the locking slots 421 is convenient for disassembling.

In some embodiments, as shown in FIG. 3, positioning bumps 14 are arranged at edges of the through holes 13 respectively at an outer side of the fixation panel 11. An outer curvature of each of the positioning bumps 14 is adapted to an outer curvature of the locking slot 421, so that the locking slots 421 can be stuck at outer sides of the positioning bumps 14, respectively. The positioning bumps 14 configured as such are characterized in convenience in positioning the plurality of PCIE card connectors 4.

In some embodiments, the locking piece 21 is movably connected to the pressing fixation plate 2, that is, the locking piece 21 can move forward and backward, and the distance from the outer end of the locking piece 21 to the plane of the pressing fixation plate 2 can be adjusted according to requirements.

In some embodiments, the die casting 3 is provided with an adjustment screw configured to adjust tightness of the torsion spring 311. By configuration of the adjustment screw, the interval between the two torsion arms of the torsion spring 311 can be adjusted, in this way, the tightness of the torsion spring 311 can be adjusted after the locking piece 21 is inserted therein. For example, in the case that it is not necessary to frequently release the fixation of the PCIE cards 100 after the locking pieces 21 are snap fitted into the torsion springs, then the adjustment screw can be screwed tightly to make each locking piece 21 uneasy to be released from the two torsion arms of the corresponding torsion spring 311. In particular, the adjustment screw is arranged at one side of the die casting 3 where connection hole is defined and aligned with the locking hole 32. The connection hole is provided with internal threads, while a surface of the adjustment screw is provided with external threads. When the adjustment screw passes through the connection hole, an inner end of the adjustment screw is located just outside the torsion arms of the torsion spring 311. When adjustment is required, it is only necessary to turn the adjustment screw so that the inner end of the adjustment screw is in contact with the torsion arms of the torsion spring 311, so as to apply different degrees of pressure to the torsion arms of the torsion spring 311.

The above are only specific embodiments of the present application, but the protection scope of the present application is not limited to the above. Those skilled in the art can easily think of various equivalents within the technical scope disclosed by the present application. Modifications or substitutions should be included within the protection scope of the present application. Therefore, the protection scope of the present application should be subject to the protection scope of the claims.

1. A tool-free peripheral component interconnect express (PCIE) fixing apparatus, comprising:
a Riser module bracket;
a plurality of peripheral component interconnect express (PCIE) card connectors, with each of the plurality of PCIE card connectors configured to fix a peripheral component interconnect express (PCIE) card;
a die casting, being in an upright state and fixed at one side of the Riser module bracket along a width direction of the Riser module bracket; and
a pressing fixation plate, being in an upright state and pivoted at one side of the Riser module bracket along the width direction of the Riser module bracket;
wherein
an inner side of the pressing fixation plate is provided with locking pieces; the die casting defines therein locking holes configured to form elastic snap-fitting connection with the locking pieces, respectively; each of the plurality of PCIE card connectors defines therein a locking slot configured to allow one of the locking pieces to pass through; and
the pressing fixation plate is configured to:
be rotated inward to enable free ends of the locking pieces to pass through the locking slots and be locked into the corresponding locking holes, whereby achieving position limitation and fixation of a plurality of the PCIE cards; and
be rotated outward to enable locking pieces to be released from the corresponding locking holes, whereby releasing the position limitation and fixation of the plurality of the PCIE cards.

2. The tool-free PCIE fixing apparatus according to claim 1, wherein
the die casting defines therein torsion spring mounting slots;
torsion springs are installed within the torsion spring mounting slots, respectively; and
in a state that the torsion springs are installed within the torsion spring mounting slots, two torsion arms of each of the torsion springs are kept in parallel, and a width of an interval between the two torsion arms is smaller than a width of a corresponding locking hole.

3. The tool-free PCIE fixing apparatus according to claim 2, wherein
each of the locking pieces comprises a rod portion and an end portion;
an inner end of the rod portion is in vertically fixed connection with the pressing fixation plate, and an outer end of the rod portion is in fixed connection with the end portion;
a diameter of the end portion is greater than the width of the interval between the two torsion arms of each of the torsion springs.

4. The tool-free PCIE fixing apparatus according to claim 3, wherein the end portion is in a spherical or circular shape.

5. The tool-free PCIE fixing apparatus according to claim 1, wherein
the Riser module bracket comprises a fixation panel;
the pressing fixation plate is pivoted at the fixation panel;
the die casting is fixed at an inner side of the fixation panel; and
the fixation panel defines therein through holes at positions corresponding to the locking holes.

6. The tool-free PCIE fixing apparatus according to claim 5, wherein
the Riser module bracket comprises a first connecting panel and a second connection panel;
in a state where the PCIE cards are installed within the Riser module bracket, a length direction of the first connection panel corresponds to a length direction of each of the PCIE cards, and a length direction of the second connection panel corresponds to a width direction of each of PCIE cards; and
an end surface of one end of the second connection panel away from the first connection panel is served as the fixation panel.

7. The tool-free PCIE fixing apparatus according to claim 6, wherein
an edge of a side surface of the fixation panel is provided with a first rolling edge;
an edge of a side surface of the pressing fixation plate is provided with a second rolling edge matching with the first rolling edge; and
the first rolling edge and the second rolling edge are connected via a pin.

8. The tool-free PCIE fixing apparatus according to claim 5, wherein
each of the plurality of PCIE card connectors comprises a connection portion and a matching portion;
the connection portion is fixed at a side surface in a width direction of each of the PCIE cards;
the matching portion is connected with the connection portion in a manner perpendicular to each other;
the matching portion is arranged at an outer side of the fixation panel and in parallel with the fixation panel; and
the matching portion defines therein a locking slot.

9. The tool-free PCIE fixing apparatus according to claim 8, wherein an opening of the locking slot faces upwards.

10. The tool-free PCIE fixing apparatus according to claim 5, wherein
positioning bumps are arranged at edges of the through holes, respectively, at an outer side of the fixation panel; and
an outer curvature of each of the positioning bumps is adapted to an outer curvature of the locking slot, so that the locking slots can be stuck at outer sides of the positioning bumps, respectively.
